(19) United States
(12) Patent Application Publication
(10) Pub. No.: US 2026/0086156 A1
(43) Pub. Date: Mar. 26, 2026

(54) SYSTEM AND METHOD FOR PREDICTING STATE OF CHARGE (SOC) OF BATTERY

(71) Applicant: JIO PLATFORMS LIMITED, Ahmedabad (IN)

(72) Inventors: Anirudh YADAV, Bhopal (IN); Adrish RAY, Bengaluru (IN); Aatreyee SARKAR, Mumbai (IN); Gulprit SINGH, Bengaluru (IN)

(73) Assignee: JIO PLATFORMS LIMITED, Ahmedabad (IN)

(21) Appl. No.: 19/217,901

(22) Filed: May 23, 2025

(30) Foreign Application Priority Data
May 25, 2024 (IN) 202421040791

(51) Int. Cl. G01R 31/367; G01R 31/371; G01R 31/3842; G06N 3/0985

(52) U.S. Cl. CPC G01R 31/367; G01R 31/371; G01R 31/3842; G06N 3/0985

(57) ABSTRACT

The present disclosure provides a system (108) and a method for predicting state of charge (SOC) of battery using deep neural network. The system (108) initiates detection and selection of a set of data parameters from a dataset corresponding to a battery of a battery management system. The DNN model is built for charging and discharging functions. The set of data parameters is normalized and the normalized data parameters are fed to the DNN model. The DNN model is run on an edge device (104) to predict the SOC of the battery in real-time, and return the value of SOC to the battery management system.

### RESERVATION OF RIGHTS

A portion of the disclosure of this patent document contains material, which is subject to intellectual property rights such as but are not limited to, copyright, design, trademark, integrated circuit (IC) layout design, and/or trade dress protection, belonging to Jio Platforms Limited (JPL) or its affiliates (hereinafter referred as owner). The owner has no objection to the facsimile reproduction by anyone of the patent document or the patent disclosure, as it appears in the Patent and Trademark Office patent files or records, but otherwise reserves all rights whatsoever. All rights to such intellectual property are fully reserved by the owner.

### FIELD OF INVENTION

The embodiments of the present disclosure generally relate to a field of wireless communication, and specifically to a system and a method for predicting state of charge (SOC) of battery using deep neural network.

### BACKGROUND OF INVENTION

Lithium-ion batteries are widely used as energy storage systems in various applications, including electric vehicles, consumer electronics, and renewable energy systems. The estimation of state of charge (SOC) of a lithium-ion battery is a crucial task in its operation and control. Accurate SOC estimation is required to ensure the battery's safe and reliable operation and to prevent overcharging or undercharging, which can lead to performance degradation and even battery failure.

State of charge prediction with a traditional technique like Coulomb counting is prone to errors. A deep learning-based approach for SOC estimation is provided in conventional arts using a convolutional neural network (CNN) along with Long Short-Term Memory (LSTM) networks. The model was trained on a dataset of battery voltage and current measurements and achieved a Mean Squared Error (MSE) value under 2%. MSE was comparatively even after using more processing power (i.e. using a combination of 2 neural networks).

An artificial neural network-based approach to estimate power consumed by batteries is traditionally known in the art. A neural network is developed that predicts the battery terminal voltage by taking inputs like initial SOC and current flowing in the battery. Artificial neural networks are capable of self-adapting to the internal parameter variations which makes them ideal real-time use cases with dynamic voltage and current profiles. However, the dependence of the SOC on internal resistance is not considered.

There is, therefore, a need in the art to provide an improved system and a method to predict the SOC of a battery by overcoming the deficiencies of the prior art(s).

### OBJECTS OF THE INVENTION

It is an object of the present disclosure to provide a system and a method for predicting state of charge (SOC) of battery using deep neural network.

It is an object of the present disclosure to provide a system with real-time SOC prediction that helps to reduce latency which is crucial.

It is an object of the present disclosure to provide a system with edge-AI devices that makes the prediction faster and accurate.

It is an object of the present disclosure to provide a scalable system and method with neutral network driven only by data.

It is an object of the present disclosure to provide an accurate, efficient, and low-overhead SOC estimation system and method on edge devices.

It is an object of the present disclosure to provide a system having an optimized Deep Neural Network (DNN) model for edge computing platforms, allowing for real-time SOC estimation without the need for cloud computing.

### SUMMARY

In an aspect, the present disclosure relates to a system and a method for predicting SOC of battery using deep neural network. The system includes one or more processors and a memory operatively coupled to the one or more processors. The memory comprises processor-executable instructions, which on execution, cause the one or more processors to detect a set of data parameters corresponding to a battery of a battery management system, convert a trained Deep Neural Network (DNN) model for charging and discharging functions into a configuration file and load the configuration file on an edge device (104), determine, using the trained DNN model via the edge device (104), the SOC of the battery, and transmit the predicted SOC value to the battery management system.

In an embodiment, the set of data parameters may include at least one of: voltage, current, temperature, age, chemical composition, or any combination thereof.

In an embodiment, the set of data parameters of the battery may be detected at regular intervals to capture variations in performance of the battery under different conditions.

In an embodiment, the one or more processors may be configured to train the DNN model by being configured to initialize data corresponding to the battery, train the DNN model based on the data, and determine if a loss function reaches an acceptable value.

In an embodiment, in response to a determination that the loss function reaches the acceptable value, the processor may be configured to store the trained DNN model in a database associated with the system, and in response to a determination that the loss function is less than the acceptable value, the processor may be configured to re-tune hyper parameters of the DNN model, and re-train the DNN model.

In another aspect, the present disclosure relates to a method for predicting a state of charge (SOC) of a battery, where the method includes detecting, by a processor, a set of data parameters corresponding to a battery of a battery management system, converting, by the processor, a trained Deep Neural Network (DNN) model for charging and discharging functions into a configuration file and loading the configuration file on an edge device, determining, using the trained DNN model via the edge device, the SOC of the battery, and transmitting, by the processor, the predicted SOC value to the battery management system.

In another aspect, the present disclosure relates to a user equipment (UE), including a processor configured to receive a trained Deep Neural Network (DNN) model and a set of data parameters corresponding to a battery of a battery management system, convert the trained DNN model into a configuration file, predict, using the trained DNN mode, a State of Charge (SOC) value of the battery, and transmit the SOC value to the battery management system.

### BRIEF DESCRIPTION OF DRAWINGS

The accompanying drawings, which are incorporated herein, and constitute a part of this disclosure, illustrate exemplary embodiments of the disclosed methods and systems which like reference numerals refer to the same parts throughout the different drawings. Components in the drawings are not necessarily to scale, emphasis instead being placed upon clearly illustrating the principles of the present disclosure. Some drawings may indicate the components using block diagrams and may not represent the internal circuitry of each component. It will be appreciated by those skilled in the art that disclosure of such drawings includes the disclosure of electrical components, electronic components, or circuitry commonly used to implement such components.

FIG. 1 illustrates an exemplary network architecture (100) for implementing a proposed system (108), in accordance with an embodiment of the present disclosure.

FIG. 2 illustrates an exemplary block diagram (200) of a system (108) for predicting state of charge (SOC) of battery using deep neural network, in accordance with an embodiment of the present disclosure.

FIG. 3 illustrates a flow diagram of an example method (300) for predicting SOC of battery using deep neural network, in accordance with embodiments of the present disclosure.

FIG. 4 illustrates an exemplary computer system (400) in which or with which embodiments of the present disclose may be utilized in accordance with embodiments of the present disclosure.

The foregoing shall be more apparent from the following more detailed description of the disclosure.

### DETAILED DESCRIPTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the disclosure as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail to avoid obscuring the embodiments.

Also, it is noted that individual embodiments may be described as a process that is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive in a manner similar to the term “comprising” as an open transition word without precluding any additional or other elements.

Reference throughout this specification to “one embodiment” or “an embodiment” or “an instance” or “one instance” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is for the purpose of describing particular embodiments only and is not intended to be limiting of the disclosure. As used herein, the singular forms “a”, “an”, and “the” are intended to include the plural forms as well, unless the context indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The present disclosure provides a system and a method for predicting state of charge (SOC) of battery using deep neural network. The system proposes a deep neural network (DNN) based approach to estimate the SOC of a lithium-ion battery accurately, efficiently, and with low computational overhead, on edge AI. The DNN model is trained using experimental data. The DNN model is optimized for edge computing platforms, allowing for real-time SOC estimation without the need for cloud computing. Results show that the proposed approach achieves high accuracy and can be implemented on edge devices for real-time SOC estimation.

The system revolves around the applications of Machine Learning and Artificial Intelligence and the present disclosure relates to monitoring various parameters of battery systems used in telecommunication towers, electric vehicles, and consumer electronics.

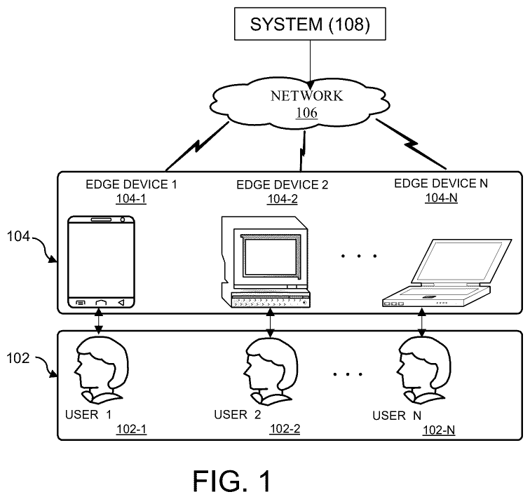

Various embodiments of the present disclosure will be explained in detail with reference to FIGS. 1-4.

FIG. 1 illustrates an exemplary network architecture (100) for implementing a proposed system (108), in accordance with an embodiment of the present disclosure.

As illustrated in FIG. 1, by way of example and not by not limitation, the exemplary network architecture (100) may include a plurality of edge devices (104-1, 104-2 . . . 104-N), which may be individually referred as the edge device (104) and collectively referred as the edge devices (104). The edge devices (104) may be associated with a plurality of users (102-1, 102-2 . . . 102-N). The plurality of users (102-1, 102-2 . . . 102-N) may be individually referred as the user (102) and collectively referred as the users (102). It may be appreciated that the edge device (104) may be interchangeably referred to as a computing device, sender device, a user device, a client device, edge Artificial Intelligence (AI) device, or a User Equipment (UE).

In an exemplary embodiment, the system (108) accurately estimates or predicts a State of Charge (SOC) of a battery associated with a battery management system (BMS).

In some embodiments, the edge device (104) may include routers, routing switches, integrated access devices, multiplexers, and a variety of metropolitan area network and wide area network access devices and the like. The edge devices are the connectors followed by smart devices with a battery operating in a smart environment, for example, an Internet of Things (IoT) system. The smart devices may be, for example, but are not limited to, a set-up box, a smart television (TV), a streaming media player, a media centre personal computer (PC), and so on. It may be appreciated that the system (108) revolves around the applications of machine learning and AI, and the disclosure relates to monitoring various parameters of battery systems.

A person of ordinary skill in the art will appreciate that the that the edge device (104) may not be restricted to the mentioned devices and various other devices may be used.

In an exemplary embodiment, the edge device (104) may communicate with the system (108) through a network (106). In an embodiment, the system (108) may be associated with the edge device (104). The network (106) may include, by way of example but not limitation, at least a portion of one or more networks having one or more nodes that transmit, receive, forward, generate, buffer, store, route, switch, process, or a combination thereof, etc. one or more messages, packets, signals, waves, voltage or current levels, some combination thereof, or so forth. The network (106) may include, by way of example but not limitation, one or more of: a wireless network, a wired network, an internet, an intranet, a public network, a private network, a packet-switched network, a circuit-switched network, an ad hoc network, an infrastructure network, a public-switched telephone network (PSTN), a cable network, a cellular network, a satellite network, a fiber optic network, some combination thereof. It may be appreciated that the network (106) may be interchangeably referred to as a home network.

Although FIG. 1 shows exemplary components of the network architecture (100), in other embodiments, the network architecture (100) may include fewer components, different components, differently arranged components, or additional functional components than depicted in FIG. 1. Additionally, or alternatively, one or more components of the network architecture (100) may perform functions described as being performed by one or more other components of the network architecture (100).

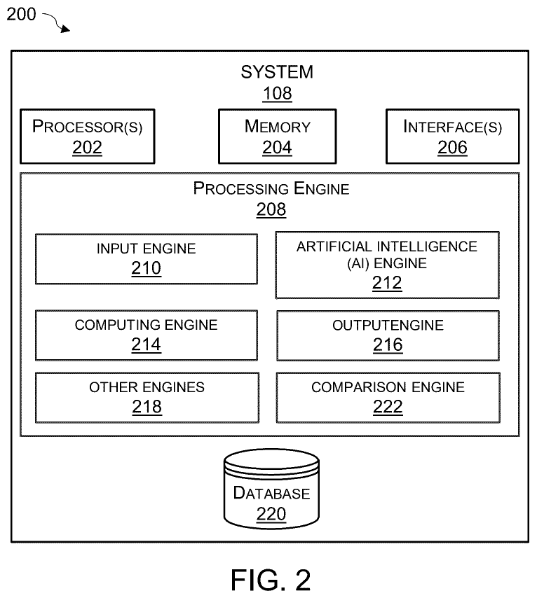

FIG. 2 illustrates an exemplary block diagram (200) of a system (108) for predicting SOC of battery using deep neural network, in accordance with an embodiment of the present disclosure.

In an embodiment, and as shown in FIG. 2, the system (108) may include one or more processors (202). The one or more processors (202) may be implemented as one or more microprocessors, microcomputers, microcontrollers, digital signal processors, central processing units, logic circuitries, and/or any devices that manipulate data based on operational instructions. Among other capabilities, the one or more processors (202) may be configured to fetch and execute computer-readable instructions stored in a memory (204) of the system (108). The memory (204) may store one or more computer-readable instructions or routines, which may be fetched and executed to create or share the data units over a network service. The memory (204) may comprise any non-transitory storage device including, for example, volatile memory such as Random-Access Memory (RAM), or non-volatile memory such as an Erasable Programmable Read-Only Memory (EPROM), a flash memory, and the like.

In an embodiment, the system (108) may also include an interface(s) (206). The interface(s) (206) may include a variety of interfaces, for example, a variety of interfaces, for example, interfaces for data input and output devices, referred to as I/O devices, storage devices, and the like. The interface(s) (206) may facilitate communication of the system (108) with various devices coupled to it. The interface(s) (206) may also provide a communication pathway for one or more components of the system (108). Examples of such components include, but are not limited to, processing engine(s) (208) and a database (220).

In an embodiment, the processing engine(s) (208) may be implemented as a combination of hardware and programming (for example, programmable instructions) to implement one or more functionalities of the processing engine(s) (208). In examples, described herein, such combinations of hardware and programming may be implemented in several different ways. For example, the programming for the processing engine(s) (208) may be processor-executable instructions stored on a non-transitory machine-readable storage medium and the hardware for the one or more processors (202) may comprise a processing resource (for example, one or more processors), to execute such instructions. In the present examples, the machine-readable storage medium may store instructions that, when executed by the processing resource, implement the processing engine(s) (208). In such examples, the system (108) may comprise the machine-readable storage medium storing the instructions and the processing resource to execute the instructions, or the machine-readable storage medium may be separate but accessible to the system (108) and the processing resource. In other examples, the processing engine(s) (208) may be implemented by an electronic circuitry.

In an embodiment, the database (220) may comprise data that may be either stored or generated as a result of functionalities implemented by any of the components of the processors (202) or the processing engine(s) (208) or the system (108).

In an exemplary embodiment, the processing engine(s) (208) may include one or more engines selected from any of an input engine (210), artificial intelligence (AI) engine (212), a computing engine (214), an output engine (216), a comparison engine (222), and other engines (218). The other engines (218) may include, but are not limited to, a monitoring engine, a normalization engine, a detection engine, a training engine, or the like.

In an embodiment, the one or more processors (202), via the input engine (210), may detect a set of data parameters corresponding to a battery of a battery management system. In response to the detection, the one or more processors (202) may normalize the set of data parameters to ensure that features of the set of data parameters are transformed within a specific similar range. The one or more processors (202) may train and save a DNN model. The one or more processors (202), via the computing engine (214), may tune the set of data parameters of the DNN model, if the comparison engine (222) determines that a loss function of the set of data parameters is less than a predetermined acceptable value. Based on the loss function, the one or more processors (202), via the AI engine (212), may build the DNN model for charging and discharging functions. The one or more processors (202) may convert the built DNN model into a configuration file and load the configuration file on an edge device (104). The one or more processors (202) may run the DNN model on the edge device (104) and predict the SOC value of the battery in real-time. In response to the predicted SOC value, the one or more processors (202), via the output engine (216), may transmit the predicted SOC value to the battery management system.

In an embodiment, the set of data parameters may include, but not limited to, voltage, current, temperature, age, chemical composition, or any combination thereof. The set of data parameters of the battery are detected at regular intervals to capture variations in performance of the battery under different conditions. The predicted SOC value is used for battery management and control. The DNN model is optimized for edge computing platforms, allowing for real-time SOC prediction without the need for cloud computing.

In an embodiment, the DNN model is trained by initiating data corresponding to the battery, and train the DNN model based on the data. In some embodiments, the comparison engine (222) may determine if the loss function reaches an acceptable value. If yes, the trained model is stored in the database (220). If no, hyper parameters the DNN model are re-tuned, and the model is re-trained.

In accordance with embodiments of the present disclosure, the neural network-based approach has more accuracy. Even though neural network-based SOC prediction algorithm exists, the DNN model is optimized for edge computing platforms, allowing for real-time SOC estimation without the need for cloud computing. AI or neural network algorithms may run on cloud environments. This involves data transfer over the Internet where there is a higher latency and issues with privacy. Using edge AI processors in the present disclosure, the latency is reduced by performing the analysis on the battery system, which is a more secure environment. This way, some tasks may be offloaded from a main controller so that the battery management system may carry out critical tasks more efficiently. The edge AI device may receive the input from the battery management system, perform the necessary processing, and return the SOC, irrespective of the power consumed. As this approach is mainly data oriented, changing between cell chemistries becomes easier.

Although FIG. 2 shows exemplary components of the system (108), in other embodiments, the system (108) may include fewer components, different components, differently arranged components, or additional functional components than depicted in FIG. 2. Additionally, or alternatively, one or more components of the system (108) may perform functions described as being performed by one or more other components of the system (108).

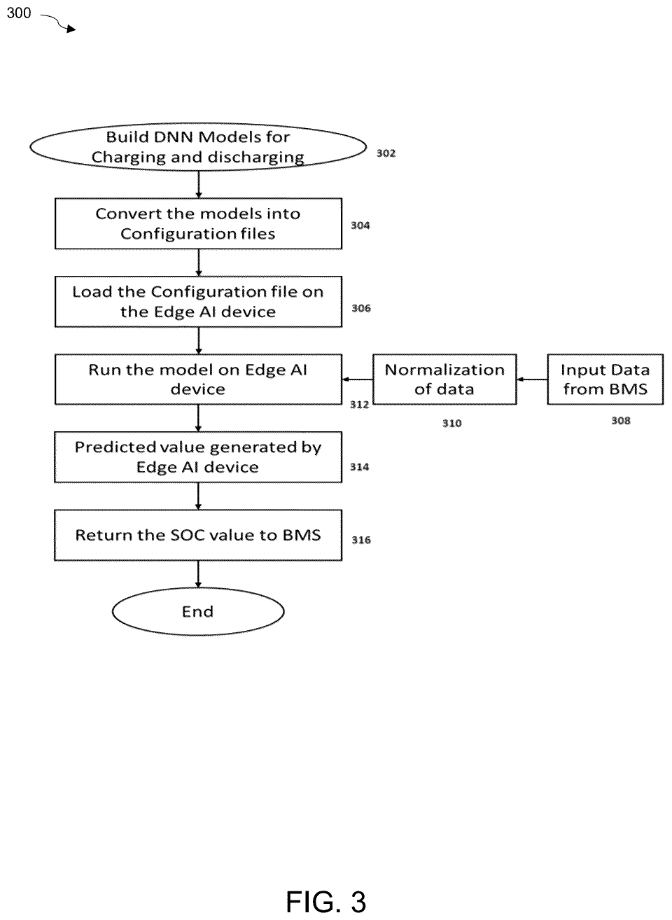

FIG. 3 illustrates a flow diagram of an example method (300) for predicting SOC of battery using deep neural network, in accordance with embodiments of the present disclosure.

With reference to FIG. 3, at 302, a DNN model is built for charging and discharging functions. In some embodiments, the DNN model is trained using a large dataset of battery current and voltage measurements and their corresponding SOC values. The dataset is divided into charging and discharging data. These two datasets are pre-processed to remove any outliers and normalize the data to improve the performance of the DNN model.

At 304, the DNN model is converted into a configuration file. At 306, the configuration file is loaded on one or more edge AI devices.

At 308, the set of data parameters corresponding to the battery are collected and detected from the battery management system. At 310, the set of data parameters are normalized.

At 312, the DNN model is run on the edge AI devices for the set of the data parameters. At 314, the SOC value of the battery is predicted or estimated in real-time using the trained DNN model. The DNN is evaluated using different batch sizes and epochs and the best model is selected for deployment.

At 316, in response to the predicted SOC value, the predicted SOC value is transmitted to the battery management system. The best models for both, charging data and discharging data, are acquired and are then deployed on the edge AI device for real-time SOC estimation of a lithium-ion battery. In some embodiments, the edge device receives the battery's current and voltage measurements and feeds them to the DNN model for SOC estimation. The estimated SOC value is then used for battery management and control.

In some embodiments, the SOC estimation approach is based on a DNN architecture that takes as input the battery's current and voltage measurements and outputs the estimated SOC. The DNN architecture is designed to be lightweight and efficient, suitable for implementation on the edge AI devices with limited processing power. The input layer receives the battery's current and voltage measurements as input, and the hidden layer performs feature extraction and non-linear transformations. The output layer generates the estimated SOC value.

In an exemplary embodiment, the proposed approach is designed to overcome the limitations of traditional SOC estimation methods and provide accurate, efficient, and low-overhead SOC estimation on edge AI devices. The experimental results demonstrate that the proposed DNN-based approach accurately estimates the SOC of a lithium-ion battery, with a mean squared error (MSE) of 0.136% for charging and MSE of 0.177% for discharging, whereas the conventional Coulomb counting can predict SOC of a lithium-ion battery with a mean squared error (MSE) of 1.56% for charging dataset and 3.41% for discharging dataset. The calculation is shown in table 1 below.

TABLE 1

| | Batch | Batch | Batch | Batch |
|---|---|---|---|---|
| | size = 128, | size = 128, | size = 256, | size = 256, |
| | epoch = | epoch = | epoch = | epoch = |
| Dataset | 1000 | 2000 | 1000 | 2000 |

MSE at different epoch and batch sizes:

| | | | | |
|---|---|---|---|---|
| Charging | 0.312 | 0.136 | 0.331 | 0.156 |
| Discharging | 0.232 | 0.177 | 0.710 | 0.216 |

MAE at different epoch and batch sizes

| | | | | |
|---|---|---|---|---|
| Charging | 0.350 | 0.275 | 0.355 | 0.278 |
| Discharging | 0.340 | 0.311 | 0.347 | 0.357 |

In an exemplary embodiment, the traditional SOC estimation techniques are model-based approaches, and the method is dependent on the type of battery used. The present neural network-based approach is data driven. Hence, it is scalable. Real-time SOC prediction on the device helps to reduce latency which may be crucial for various applications. There is no need for the data to move to the cloud for the analysis. Edge AI makes the prediction faster and accurate.

In an embodiment, the present disclosure may relate to a non-transitory computer-readable medium comprising processor-executable instructions that cause a processor (202) to perform the methods discussed herein.

In an exemplary embodiment, Multi-Layer Perceptron (MLP) Neural Network may be trained by selecting the required parameters from the dataset and then normalizing it. Normalization is the process of transforming data to bring it within a range. In some embodiments, the normalized data is divided into training and test set in the ration of 80:20. The initial hyper parameters are selected for training the neural network and the training is started. If an acceptable loss or accuracy value is reached, then the model is saved. Otherwise, the hyper parameters are updated and steps are repeated again till an acceptable value is reached.

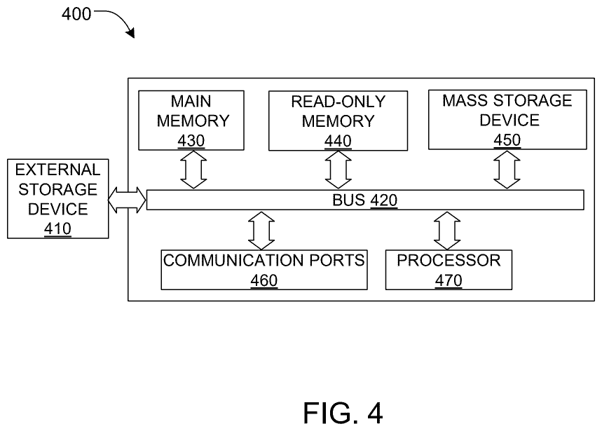

FIG. 4 illustrates an exemplary computer system (400) in which or with which embodiments of the present disclose may be utilized in accordance with embodiments of the present disclosure. It may be appreciated that the system (108) and/or the edge AI device (104) may be implemented as the computer system (400).

As shown in FIG. 4, the computer system (400) may include an external storage device (410), a bus (420), a main memory (430), a read-only memory (440), a mass storage device (450), a communication port(s) (460), and a processor (470). A person skilled in the art will appreciate that the computer system (400) may include more than one processor (470) and communication ports (460). The processor (470) may include various modules associated with embodiments of the present disclosure. The communication port(s) (460) may be any of an RS-232 port for use with a modem-based dialup connection, a 10/100 Ethernet port, a Gigabit or 10 Gigabit port using copper or fiber, a serial port, a parallel port, or other existing or future ports. The communication ports(s) (460) may be chosen depending on a network, such as a Local Area Network (LAN), Wide Area Network (WAN), or any network to which the computer system (400) connects.

In an embodiment, the main memory (430) may be a Random Access Memory (RAM), or any other dynamic storage device commonly known in the art. The read-only memory (440) may be any static storage device(s) e.g., but not limited to, a Programmable Read Only Memory (PROM) chip for storing static information e.g., start-up or basic input/output system (BIOS) instructions for the processor (470). The mass storage device (450) may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces).

In an embodiment, the bus (420) may communicatively couple the processor(s) (470) with the other memory, storage, and communication blocks. The bus (420) may be, e.g., a Peripheral Component Interconnect PCI)/PCI Extended (PCI-X) bus, Small Computer System Interface (SCSI), USB, or the like, for connecting expansion cards, drives, and other subsystems as well as other buses, such a front side bus (FSB), which connects the processor (470) to the computer system (400).

In another embodiment, operator and administrative interfaces, e.g., a display, keyboard, and cursor control device may also be coupled to the bus (420) to support direct operator interaction with the computer system (400). Other operator and administrative interfaces can be provided through network connections connected through the communication port(s) (460). Components described above are meant only to exemplify various possibilities. In no way should the aforementioned exemplary computer system (400) limit the scope of the present disclosure.

While considerable emphasis has been placed herein on the preferred embodiments, it will be appreciated that many embodiments can be made and that many changes can be made in the preferred embodiments without departing from the principles of the disclosure. These and other changes in the preferred embodiments of the disclosure will be apparent to those skilled in the art from the disclosure herein, whereby it is to be distinctly understood that the foregoing descriptive matter is to be implemented merely as illustrative of the disclosure and not as a limitation.

### Advantages of the Invention

The present disclosure provides a system and a method for predicting state of charge (SOC) of battery using deep neural network.

The present disclosure reduces latency by performing the analysis on the battery system which is a more secure environment.

The present disclosure provides a dedicated device to run neural network-based algorithm for SOC estimation that can offload few tasks from a main controller so that a battery management system can carry out critical tasks more efficiently.

The present disclosure provides an edge device that receives an input from a battery management system, does the necessary processing, and returns the SOC, irrespective of the power consumed.

The present disclosure provides a system and a method for predicting SOC of battery that is mainly data oriented.

The present disclosure provides a system and a method for predicting SOC of battery that is applicable in any kind of scenario whether it is an Electric Vehicle (EV) or any other static applications like telecommunication towers.

We claim:

1. A system (108) for predicting a state of charge (SOC) of a battery, the system (108) comprising:
one or more processors (202); and
a memory (204) operatively coupled to the one or more processors (202), wherein the memory (204) comprises processor-executable instructions, which on execution, cause the one or more processors (202) to:
detect a set of data parameters corresponding to a battery of a battery management system;
convert a trained Deep Neural Network (DNN) model for charging and discharging functions into a configuration file and load the configuration file on an edge device (104);
determine, using the trained DNN model via the edge device (104), the SOC of the battery; and
transmit the predicted SOC value to the battery management system.

2. The system (108) as claimed in claim 1, wherein the set of data parameters comprises at least one of: voltage, current, temperature, age, chemical composition, or any combination thereof.

3. The system (108) as claimed in claim 1, wherein the set of data parameters of the battery are detected at regular intervals to capture variations in performance of the battery under different conditions.

4. The system (108) as claimed in claim 1, wherein the one or more processors (202) are configured to train the DNN model by being configured to:
initialize data corresponding to the battery;
train the DNN model based on the data; and
determine if a loss function reaches an acceptable value.

5. The system (108) as claimed in claim 4, wherein the one or more processors (202) are configured to:
in response to a determination that the loss function reaches the acceptable value, store the trained DNN model in a database associated with the system (108); and
in response to a determination that the loss function is less than the acceptable value, re-tune hyper parameters of the DNN model, and re-train the DNN model.

6. A method (300) for predicting a state of charge (SOC) of a battery, the method (300) comprising:
detecting, by a processor (202), a set of data parameters corresponding to a battery of a battery management system;
converting, by the processor (202), a trained Deep Neural Network (DNN) model for charging and discharging functions into a configuration file and loading the configuration file on an edge device (104);
determining, using the trained DNN model via the edge device (104), the SOC of the battery; and
transmitting, by the processor (202), the predicted SOC value to the battery management system.

7. The method (300) as claimed in claim 1, wherein the set of data parameters of the battery are detected at regular intervals to capture variations in performance of the battery under different conditions.

8. The method (300) as claimed in claim 1, comprising training, by the processor (202) the DNN model by:
initializing, by the processor (202), data corresponding to the battery;
training, by the processor (202), the DNN model based on the data; and
determining, by the processor (202) if a loss function reaches an acceptable value.

9. The method (300) as claimed in claim 8, comprising:
in response to a determination that the loss function reaches the acceptable value, storing, by the processor (202), the trained DNN model in a database associated with the system (108); and
in response to a determination that the loss function is less than the acceptable value, re-tuning, by the processor (202) hyper parameters of the DNN model, and re-training the DNN model.

10. A user equipment (UE), comprising:
a processor configured to:
receive a trained Deep Neural Network (DNN) model and a set of data parameters corresponding to a battery of a battery management system;
convert the trained DNN model into a configuration file;
predict, using the trained DNN mode, a State of Charge (SOC) value of the battery; and
transmit the SOC value to the battery management system.
